(19) United States
(12) Patent Application Publication
(10) Pub. No.: US 2024/0219840 A1
(43) Pub. Date: Jul. 4, 2024

(54) METHOD FOR MANUFACTURING A TIMEPIECE COMPONENT

(71) Applicant: ROLEX SA, Geneva (CH)

(72) Inventors: Florian Calame, Epalinges (CH); Xavier Multone, Lausanne (CH)

(73) Assignee: ROLEX SA, Geneva (CH)

(21) Appl. No.: 18/293,503

(22) PCT Filed: Jul. 28, 2022
(86) PCT No.: PCT/EP2022/071255

§ 371 Date: Jan. 30, 2024

(30) Foreign Application Priority Data
Aug. 2, 2021 (EP) 21189062.9

(51) Int. Cl. G03F 7/20; G04B 19/04

(52) U.S. Cl. CPC G03F 7/201; G04B 19/042

(57) ABSTRACT

The method for manufacturing a timepiece component includes: providing (E1) a substrate having an upper surface (21); applying (E2) an anti-glare treatment to all or part of the upper surface (21) of the substrate (20); depositing (E31) a layer of photoresist (40) on the upper surface of the substrate (20); exposing (E32) the photoresist (40) to exposure radiation (45) according to a predetermined pattern; and developing (E33) the photoresist (40), so as to form a mould delimited at least partially by the photoresist (40) and by a portion of the at least one upper surface (21) of the substrate (20).

The present invention relates to a method for manufacturing a mold for the manufacture of a timepiece component. It also relates to a method for manufacturing a timepiece component that uses such a mold. It also relates to a timepiece component per se, obtained using such a method.

The existing manufacturing methods for manufacturing timepiece components are poorly-suited or not suited to the manufacture of a component of complex geometry, which is to say one comprising inclined faces, for example forming a pattern of the square-embossed “clou de paris” type, or comprising chamfers and/or bevels, sometimes referred to as “anglage” or “angling”. These methods sometimes succeed in achieving certain complex geometries, at the expense of fiddly steps such as post-machining. In general, the existing manufacturing methods for manufacturing timepiece components do not allow all the complex shapes to be manufactured with sufficient precision.

Thus, it is an object of the present invention to improve the known manufacturing methods for manufacturing a timepiece component, and notably to be able to manufacture a timepiece component of complex shape in a simple way and with a high degree of precision.

To that end, the invention relies on a method for manufacturing a mold for the manufacture of a timepiece component, characterized in that it comprises the following steps:
of procuring a substrate comprising an upper surface;
of applying a treatment having an antireflective effect to all or part of the upper surface of the substrate; then
of depositing a layer of photosensitive resin on the upper surface of the substrate;
of irradiating said photosensitive resin with an irradiating radiation according to a predefined pattern; then
of developing the photosensitive resin, so as to form a mold at least partially delimited by said photosensitive resin and by part of said upper surface of the substrate.

The invention is defined more specifically by the claims.

These objects, features and advantages of the present invention will be set out in detail in the following description of particular embodiments, given by way of nonlimiting example with reference to the appended figures, in which:

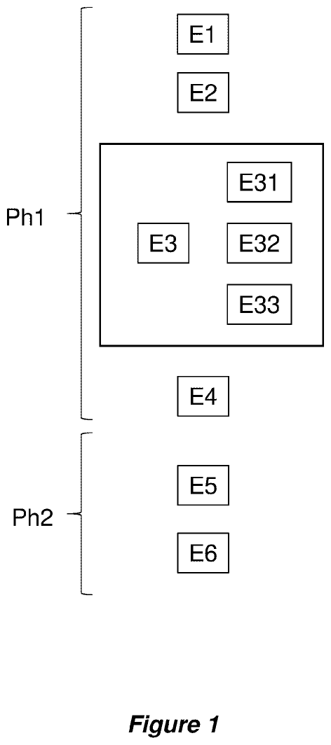

FIG. 1 schematically shows the steps of a method for manufacturing a timepiece component according to one embodiment of the invention.

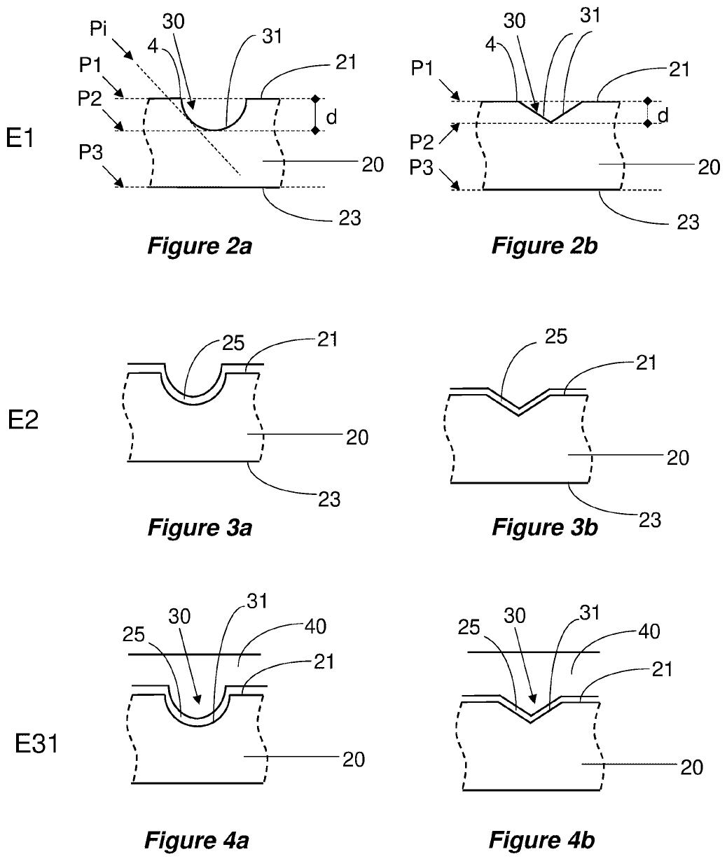

FIGS. 2a to 10a show cross-sectional views of the steps of a method for manufacturing a timepiece component according to a first embodiment of the invention.

FIGS. 2b to 10b show cross-sectional views of the steps of a method for manufacturing a timepiece component according to a second embodiment of the invention.

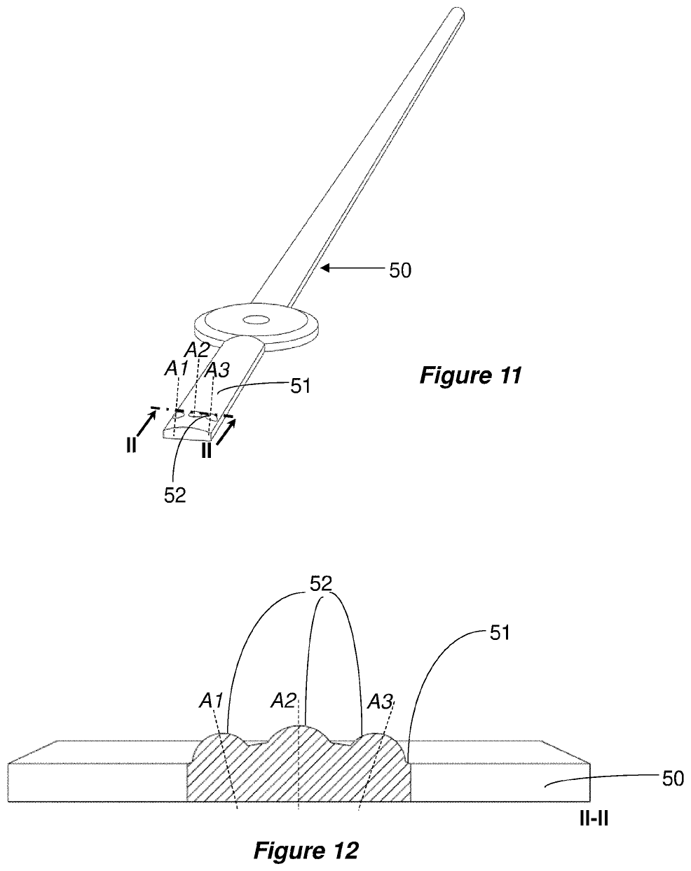

FIG. 11 shows a perspective view, from above, of a hand according to one embodiment of the invention.

FIG. 12 shows a transverse cross-sectional view of one end of the hand according to the embodiment of the invention.

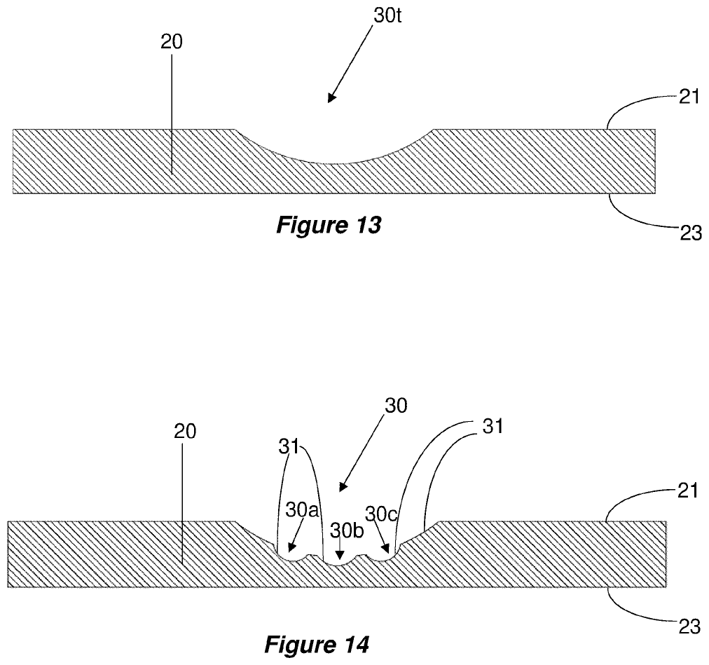

FIGS. 13 and 14 show transverse cross-sectional views of the steps of creating a hollow in a substrate in order to manufacture a mold for the manufacture of the hand according to the embodiment of the invention.

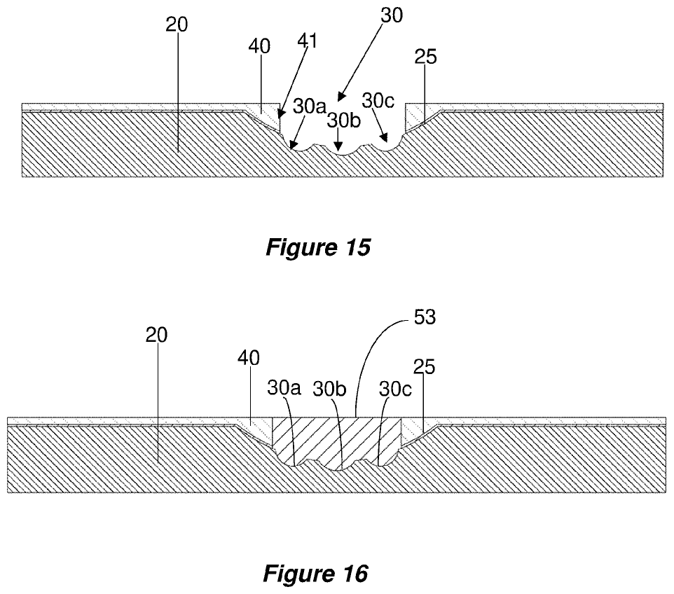

FIG. 15 shows a transverse cross-sectional view of a mold for manufacturing the hand according to the embodiment of the invention.

FIG. 16 shows a transverse cross-sectional view of a step in the manufacture of the hand in the mold according to the embodiment of the invention.

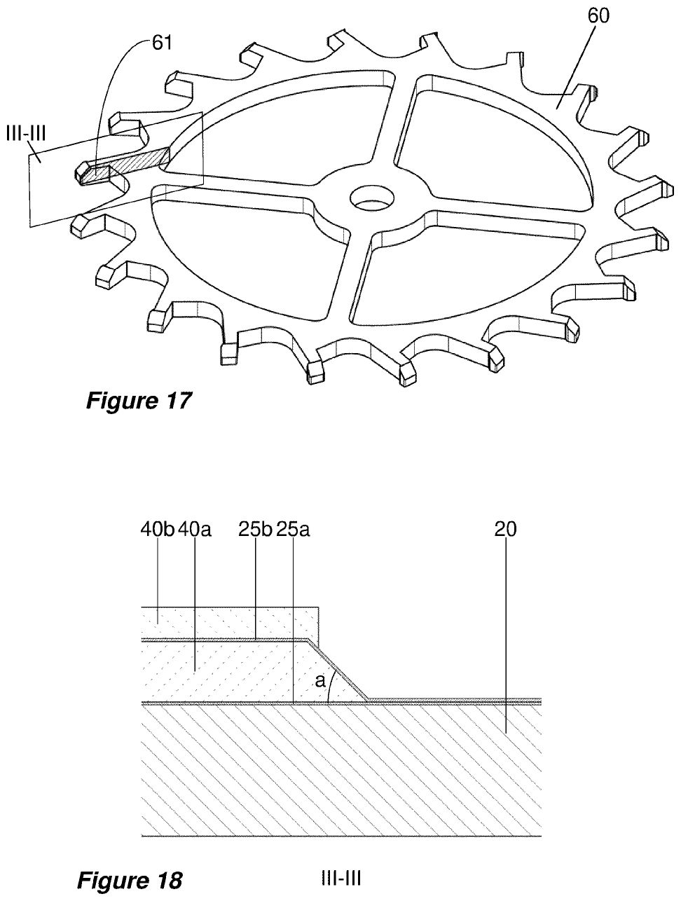

FIG. 17 shows a perspective view, from above, of an escapement wheel according to one embodiment of the invention.

FIG. 18 shows a transverse cross-sectional view of a mold for manufacturing the escapement wheel according to the embodiment of the invention.

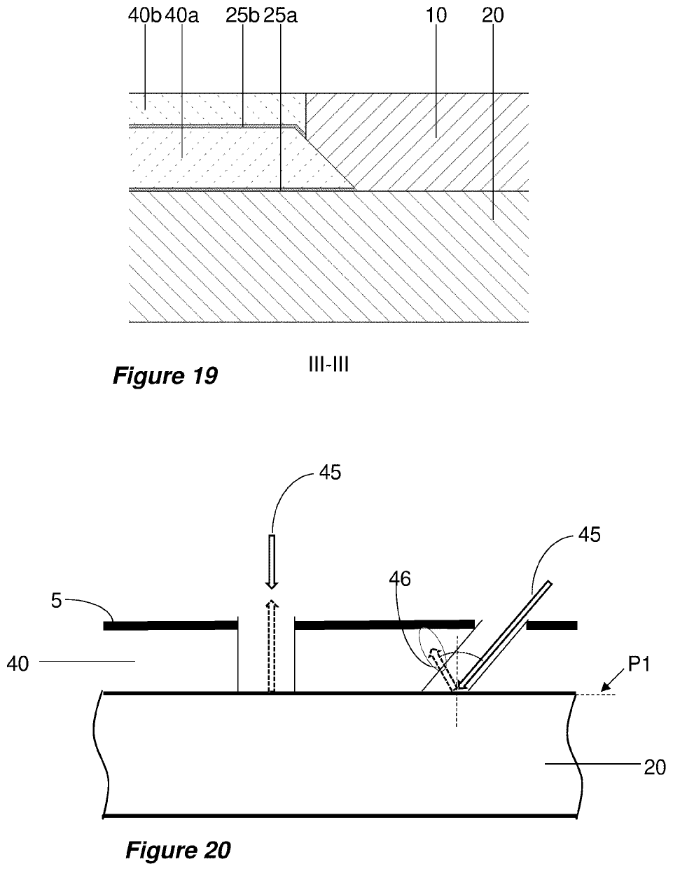

FIG. 19 shows a transverse cross-sectional view of a step in the manufacture of the escapement wheel in the mold according to the embodiment of the invention.

FIG. 20 illustrates a particular configuration liable to lead to stray irradiating radiation.

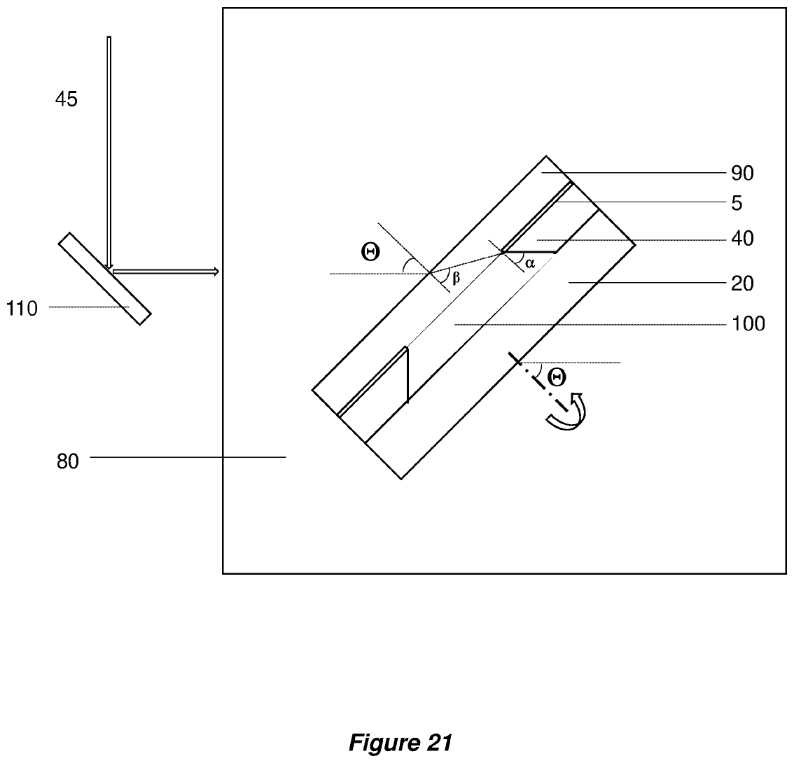

FIG. 21 illustrates the implementation of a variant of the embodiments of the invention.

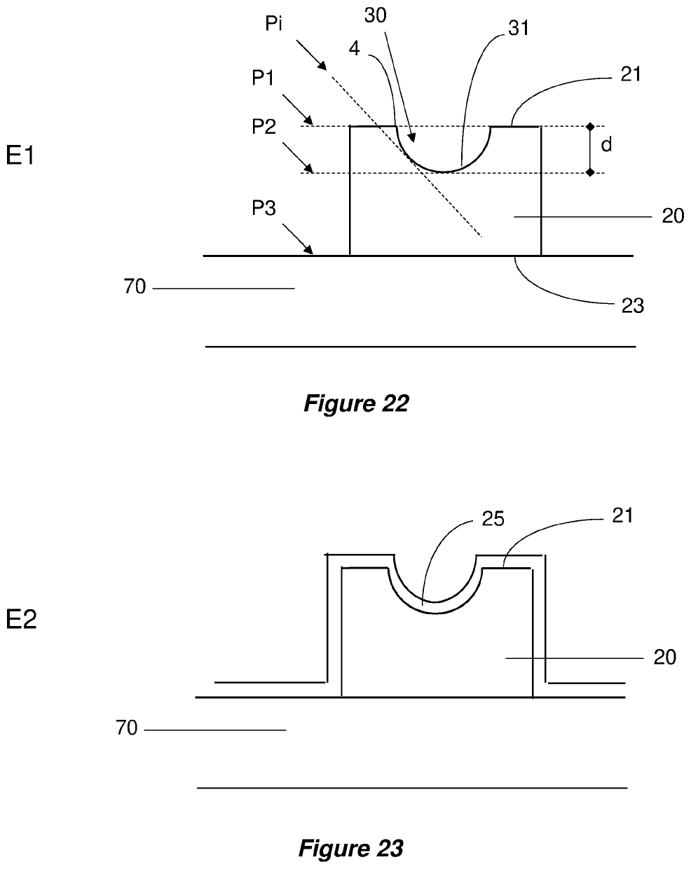

FIGS. 22 to 26 show cross-sectional views of the steps of a method for manufacturing a timepiece component according to a third embodiment of the invention.

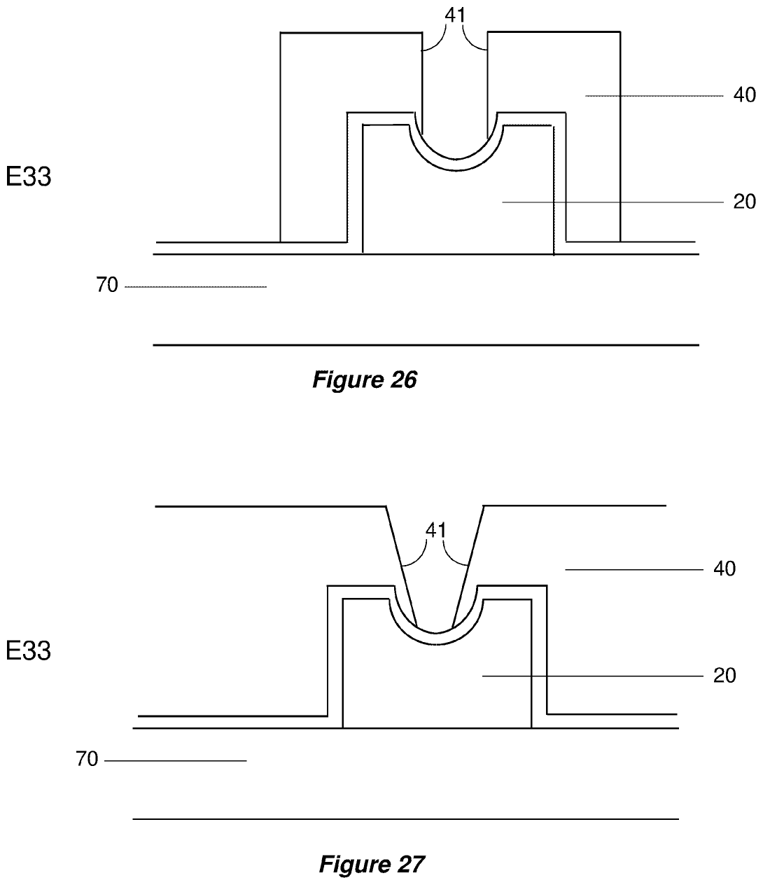

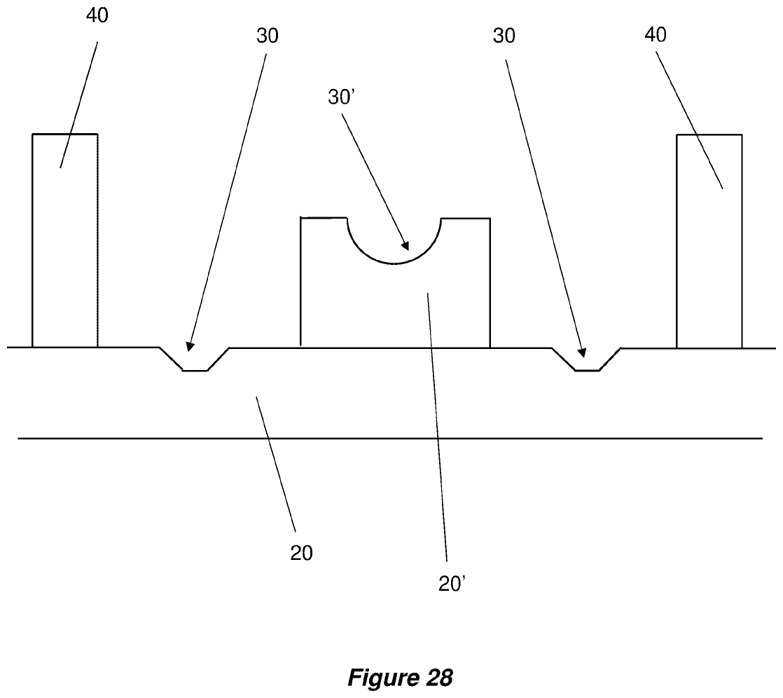

FIG. 27 shows a cross-sectional view of a variant of an assembly shown in FIG. 26.

FIG. 28 shows a cross-sectional view of a step of a method for manufacturing a timepiece component according to a fourth embodiment of the invention.

The invention achieves the desired objects through the intermediate manufacture of a specific mold, capable of exhibiting a complex shape, so as to obtain a timepiece component of complex shape simply by molding it in this specific mold. A complex shape is notably characterized by a component comprising at least one sidewall that is inclined relative to two mutually parallel main faces of the component, or inclined relative to that surface of the component that is formed by the bottom of the specific mold.

The invention relates first of all to a method for manufacturing a mold for the manufacture of a timepiece component. It next comprises a method for manufacturing a timepiece component per se, of which method the first phase Ph1 consists in implementing the method for manufacturing a mold, and the second phase Ph2 in using such a mold to manufacture a timepiece component per se, as indicated schematically in FIG. 1.

The method for manufacturing a mold for the manufacture of a timepiece component according to particular embodiments chosen by way of illustrative example will be described first of all with the support of FIGS. 2a to 10a and 2b to 10b, and also 22 to 28.

The method comprises a first step E1 consisting in procuring a substrate 20 which assumes a substantially planar shape with a thickness that is small according to the first two embodiments, ranging from a few hundred microns to a few millimeters, having an upper surface 21 and a lower surface 23 that are potentially substantially parallel. The upper surface 21 is generally planar. As a variant, it is possible for it not to be planar, for example to be domed and/or to comprise one or more hollows. In all instances, in order to simplify the description, reference will be made to the plane P1 in which this upper surface 21 extends, this plane P1 being a tangential plane in the event of a surface that is not perfectly planar, as will be specified hereinafter. The lower surface 23 likewise extends in a plane P3. The thickness of the substrate 20 is the distance between the two planes P1-P3.

Furthermore, the substrate 20 may be made from a conducting material, such as a metal or metal alloy, such as a stainless steel, or from a non-conducting material, such as silicon, glass or ceramic, or polymer, or composite, for example in the form of a plate or wafer or of a block. The substrate preferably exhibits low roughness. It may advantageously have undergone a traditional preparation step involving degreasing it, cleaning it, possibly passivating and/or activating it. In addition, the substrate may be provided with identifying marks so that it can be oriented precisely.

According to this embodiment, the first step consisting in procuring E1 a substrate 20 comprises an optional step consisting in creating a hollow 30 starting from the upper surface 21 of the substrate 20 so as to form a hollow 30 delimited by at least one inclined surface 31 that is inclined relative to the plane P1 in which said upper surface of the substrate extends apart from in the hollow. This plane P1 is considered to lie at the interface 4 between the hollow 30 and the rest of the upper surface 21 of the substrate 20, with the exception of the hollow, which is to say considering a would-be continuous upper surface at this interface 4. This interface forms a salient edge. As mentioned above, if the surface is not planar all over, this plane is the plane tangential to the upper surface 21 of the substrate outside of the hollow. Likewise, said inclined surface 31 of the hollow 30 will be considered with reference to a tangential plane Pi tangential to said inclined surface if said surface is not planar. In general, the hollow 30 comprises at least one inclined surface when it comprises at least one tangential plane Pi that is neither perpendicular nor parallel to the aforementioned plane P1.

Advantageously, the inclined surface 31 exhibits an inclination that forms an angle of between 10 and 80 degrees relative to the upper surface 21 (namely to the plane P1) at the interface 4 between this upper surface 21 and the hollow 30.

This step is optional; the substrate does not necessarily have a hollow.

FIG. 2a shows a first example of a hollow 30 having a surface that is curved, rounded, continuous and concave. It has a transverse cross section, which is to say a section on a plane perpendicular to the plane P1, that is of curved shape, forming, overall, a rounded U-shape. In this example, the hollow 30 exhibits an inclined surface 31 over substantially its entire surface.

FIG. 2b shows a second example of a hollow 30 having the form of a conical surface forming a transverse cross section that is V-shaped. As a variant, the hollow may be of triangular shape and have that same V-shaped transverse cross section. Each branch of the V forms a rectilinear section of an inclined surface 31 of the hollow 30.

Naturally, the invention is not focused on the shape of the hollow 30, which is optional, per se, and is not confined to the two embodiments illustrated. A hollow 30 may comprise an inclined surface on only a sub-section of its total surface. An inclined surface may be formed of a multitude of planar and/or curved facets, which each ultimately potentially represent an inclined surface as defined hereinabove. Additionally, it may be of concave or convex shape. In general, the inclined surface of the upper surface of the substrate, at a hollow or otherwise, is defined as being a surface that makes an angle other than 0° or other than 90° with the aforementioned plane P1. An inclined surface 31 may be continuous or discontinuous. The angle that an inclined surface makes with the plane P1 may or may not be constant. An inclined surface may be planar and/or curved. In the case of a curved surface, the above-mentioned angle may for example be characterized by the angle formed by a tangent at a given point on the inclined surface and the plane P1, this angle changing according to the profile of the inclined surface. The angle that this inclined surface forms with the plane P1 is more particularly visible in a view in cross section on a plane perpendicular to the plane P1, namely a transverse cross section as defined above. Note that in the event of a non-planar upper surface 21, this angle will be measured with respect to a plane tangential to the upper surface 21 at the interface 4. In addition, one or more hollows 30 may be formed in the substrate 20. A hollow 30 may comprise one or more inclined surfaces 31.

In addition, the hollow 30 may be formed by any means known to those skilled in the art, such as traditional mechanical machining, laser machining, laser etching, chemical etching or electrochemical dissolution. As a variant, a hollow is not formed by a specific machining step but may result directly from the manufacture of the substrate 20 of which the upper surface 21 is locally non-planar. In all cases, a hollow 30 takes the form of a surface that is recessed relative to the rest of the upper surface 21 of the substrate 20, the hollow extending into the thickness of the substrate 20 to a certain depth d.

According to a third embodiment illustrated by FIGS. 22 to 26, the substrate 20 at least partly assumes the form of a layer or of a block, in which at least one hollow 30 has been formed in the form of a recessed zone, particularly using the two-photon polymerization technique known by the acronym TPP; this substrate 20 is made of resin, or of any material that can be structured using two-photon polymerization (for example certain ormocers, photosensitive composites, and certain glass ceramics). This substrate 20 is positioned on a support 70, as illustrated in FIG. 22. In a variant which has not been depicted, the two-photon-polymerized substrate 20 may take the form of a plate of a shape similar to the substrate of the first two embodiments described.

Note that this two-photon polymerization technique used in this third embodiment offers numerous advantages including a broad capability to achieve complex shapes, with overhanging superposed zones for example, or a discontinuous structure, or a wave shape. This technique also makes it possible to achieve a high level of precision, with a definition to within 100 nm, and a roughness Ra of less than 10 nm. It also allows a large volume to be irradiated. This technique makes it possible for example to create locally inclined sidewalls that are domed and/or angled.

Alternatively, a substrate 20 made of resin or some other compatible material could be formed with a hollow, using a stereolithography or grayscale photolithography technique, with poorer resolution and limitations on shape.

The depth d of the hollow 30 corresponds to the distance measured between the plane P1 of the upper surface 21 of the substrate 20 and a plane P2, parallel to the plane P1, passing through that point of the hollow 30 that is furthest from the plane P1. This depth d is measured in a direction perpendicular to the planes P1 and P2, namely perpendicular to the upper surface 21 of the substrate 20. As a preference, the depth d of the hollow is less than or equal to 1000 μm, or even less than or equal to 500 μm, or even less than or equal to 400 μm. The depth d is also preferably greater than or equal to 10 μm, or even greater than or equal to 50 μm, or even greater than or equal to 80 μm, or even greater than or equal to 100 μm.

As will become apparent later, the hollow 30 may at least partially act as a mold for manufacturing a timepiece component. It will more specifically be used for defining a complex shape of a timepiece component, so as to allow this component to be produced advantageously by simple molding, without the need for an additional machining step. Note that the hollow therefore has a shape suited to the future demolding of that part of the timepiece component that will be molded in this hollow. For that purpose, according to one exemplary embodiment, the cross-sectional area of the hollow, in a plane parallel to the plane P1 in which the upper surface 21 of the substrate extends, at any depth, is less than the cross section of the open side of the hollow, namely at the interface 4 between the hollow 30 and the upper surface 21 of the substrate 20. According to another exemplary embodiment, the cross-sectional area of the hollow 30, parallel to the plane P1 in which the upper surface 21 of the substrate extends, decreases with increasing distance away from said plane P1. Note too that the substrate 20 has the sole function of forming part of the mold used for manufacturing the timepiece component; it does not belong to the future timepiece component. Note that the third embodiment depicted in FIGS. 22 to 26 employs a support 70 which does not form a surface of the mold or part of the future timepiece component.

As an option, not shown, a conductive layer may be deposited on all or part of the upper surface 21 of the substrate 20, notably at least partially over a hollow 30, particularly on the inclined surface thereof. Such a conductive layer is needed when the substrate is not made from a conducting material and when the second phase Ph2 of the manufacture requires a mold that is conducting, as will be specified hereinafter. This conductive layer may notably be intended to act as an electrode to initiate an electroforming, electrodeposition or electroplating step, intended to grow a future metal layer on the timepiece component. In the known way, this initiating conductive layer may comprise a sublayer of chromium, of nickel or of titanium, covered with a layer of gold or of copper, and thus exhibit a multilayer structure. Such a conductive layer may be deposited using a process of physical vapor deposition (PVD), or chemical vapor deposition (CVD), or atomic layer deposition (ALD) or pulsed laser ablation deposition (PLD), using thermal evaporation, or using any means known to those skilled in the art.

The method according to the embodiment next comprises a step consisting in applying E2 a treatment having an antireflective effect to the substrate, the purpose of which will be explained later on. According to the embodiment, this step is implemented in the form of a step consisting in depositing an antireflective layer 25 on the substrate 20 at least over part of the upper surface 21 thereof that does not lie perpendicular to incident irradiating radiation intended to irradiate the resin, which will be implemented in a subsequent step described hereinbelow. The application of an antireflective layer 25 relates particularly to the inclined surface 31 of the hollow 30 in the embodiments depicted, in the knowledge that it is generally preferable to apply irradiated radiation perpendicular to the plane P1 in which the rest of the upper surface 21 of the substrate 20 extends apart from the hollow or more generally an inclined surface. The antireflective layer 25 may extend over all or part of the upper surface 21 of the substrate 20, as shown in FIGS. 3a and 3b, or even also over part of a support 70 as shown in FIG. 23.

As a preference, the antireflective layer makes it possible to reduce the reflection of an irradiating radiation, for example UV (ultraviolet) radiation, by more than 98%, or even by more than 99%, or even by more than 99.9%. The antireflective layer may be of any chemical nature known to those skilled in the art. It may contain a material of organic origin. In particular, it may be a layer of the material known by its trade name AZ®-BARLi® II.

The treatment having an antireflective effect may comprise the depositing of an antireflective layer 25 by spin-coating or by spray-coating or by dip-coating, or by chemical vapor deposition (CVD) or by physical vapor deposition (PVD), or by atomic layer deposition (ALD) or by pulsed laser ablation deposition (PLD), or using any technique known to those skilled in the art. In a variant, the step consisting in applying E2 a treatment having an antireflective effect to the substrate may comprise a special structuring of the upper surface 21 of the substrate 20 or even of the surface of a support 70. Such physical structuring of the upper surface 21 of the substrate may notably be achieved by sandblasting, for example through use of a laser.

The method according to the embodiment next comprises a step E3 consisting in forming at least one sidewall of the mold, through the depositing of a material, notably a resin, on the upper surface of the substrate, so as to complete the mold, which is thus formed by the combination of the resin with part of the substrate. Advantageously the step consisting in depositing a material is such that it forms sidewalls of the manufacturing mold, these sidewalls supplementing the substrate, and notably part of the upper surface 21 of the substrate and optionally a hollow of this upper surface 21 of the substrate, which forms all or part of the bottom of the mold.

According to the embodiment, a resin is deposited using a photolithography technique during this step, the step comprising several sub-steps which will be detailed hereinafter.

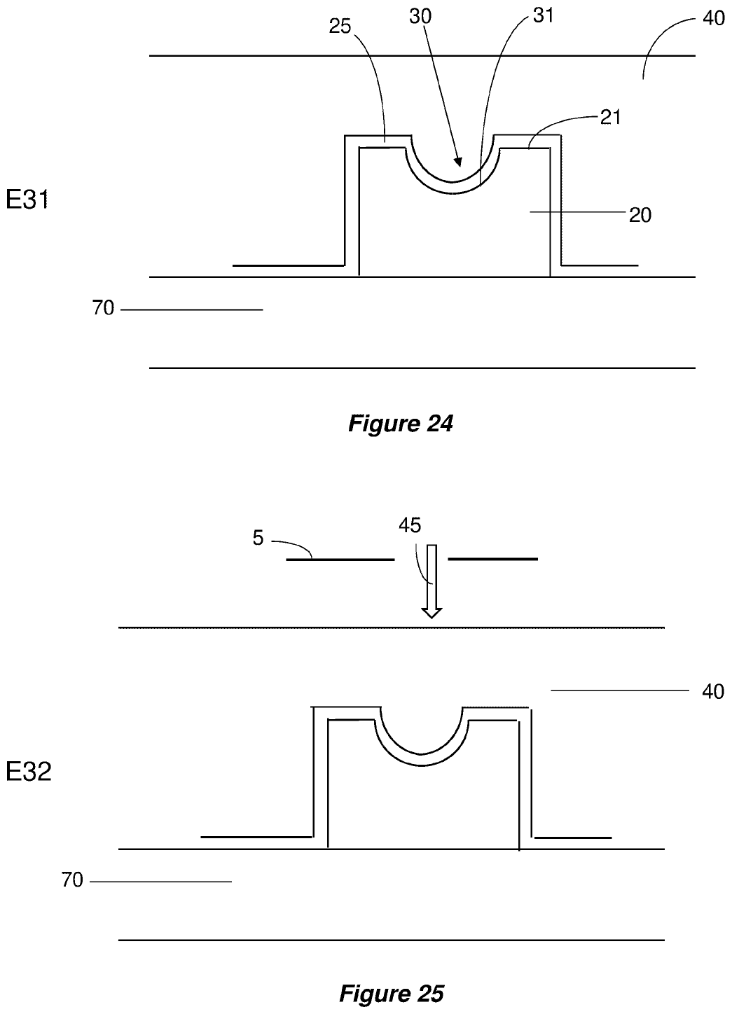

First of all, this step comprises a sub-step E31 consisting in depositing a layer of photosensitive resin 40 on all or part of the upper surface 21 of the substrate 20 and possibly of a support 70 (which may possibly be covered with a conductive layer and covered with an antireflective layer 25 as explained hereinabove), optionally notably at least partly at an inclined surface 31 of a hollow 30, as illustrated in FIGS. 4a and 4b and 24.

The photosensitive resin may be negative or positive. In the former instance, it is designed to become insoluble or difficult to dissolve in a developing solution under the action of irradiating radiation (i.e. so that the exposed zones resist development), whereas in the latter instance, it is designed to become soluble in a developing solution under the action of irradiating radiation, whereas the part not exposed to the radiation remains insoluble or difficult to dissolve.

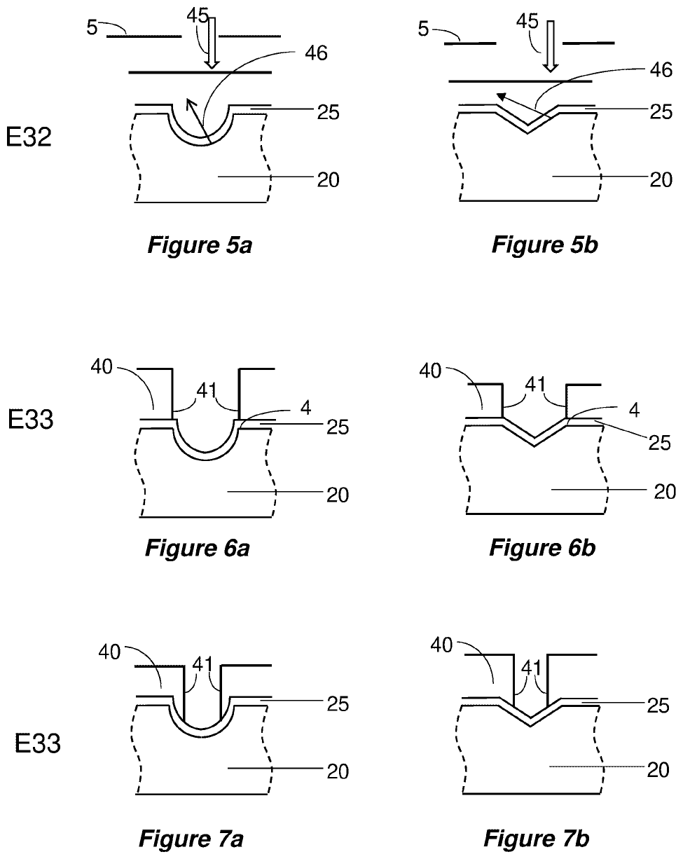

The method next comprises a sub-step E32 consisting in irradiating said photosensitive resin 40 with an irradiating radiation 45 through a mask 5 as shown in FIGS. 5a and 5b and 25. The irradiating radiation 45 may be a UV radiation irradiating the photosensitive resin 40 according to a pattern defined by the mask 5 which has openings and opaque zones corresponding to this pattern. Alternatively, the irradiation may be achieved by direct writing (therefore not requiring a mask) according to the predefined pattern, using a laser or an electron beam. The irradiating radiation 45 may be X-ray, UV, visible light, IR (infrared) radiation or an electron beam.

According to one embodiment, the irradiating radiation 45 used is perpendicular or substantially perpendicular to the plane in which the mask 5 extends, the latter being itself parallel to the plane P1 of the upper surface 21 of the substrate 20 so that only those zones of the photosensitive resin 40 that are situated directly in line with the openings formed in the mask 5 are irradiated. These irradiated zones are thus defined by sidewalls that are perpendicular or substantially perpendicular to the plane P1. These sidewalls are therefore referred to by definition as “upright sidewalls”. As an advantageous variant, the irradiating radiation 45 may be inclined relative to the plane P1 of the substrate 20, or more generally relative to the upper surface 21 of the substrate, such incident radiation then defining inclined sidewalls of resin.

The step consisting in depositing a resin next comprises a sub-step E33 consisting in developing the resin, as illustrated by FIGS. 6a, 6b, 7a and 7b, 8a, 8b, 26 and 27 according to embodiment variants. Note that FIG. 27 illustrates a variant of the assembly of FIG. 26 of the third embodiment, in which the variant is the result obtained after development, following an aforementioned step E32, during which said variant is inclined and rotated in the path of the irradiating radiation while the resin 40 of the substrate 20 is being polymerized. In the event that the resin is a negative resin, development consists in eliminating those zones of the resin that have not been irradiated, for example by dissolving them in a chemical product or using a plasma treatment. In the case of a positive photosensitive resin, the zones that have been irradiated are eliminated during development and the zones that have not been irradiated are kept on the substrate. After development, the substrate 20 is exposed in the places where the resin has been eliminated. The remaining portions of resin define the sidewalls of the mold and that part of the substrate that is circumscribed by the sidewalls of the mold defines the bottom of the mold. A mold is thus formed by the combination of part of the substrate and a part made of resin.

As explained hereinabove, the mask 5 makes it possible to define those zones of the resin that are or are not to be irradiated, so as ultimately to define the geometry of the resin mold and therefore of the mold. In order to achieve sufficient mold precision, it is important to limit, or even prevent, any stray irradiation, which is to say any irradiating radiation that may reach the resin where such irradiation is not desired. Such stray irradiating radiation 46 may be brought about in the way depicted in FIGS. 5a and 5b in the absence of any antireflective treatment of the substrate 20. Specifically, stray irradiated radiation 46 may be the result of reflection of the incident irradiating radiation 45 off a surface of the substrate 20, leading to reflected irradiation that reaches the resin in zones where this is not desired. In particular, stray irradiating radiation may be capable of reaching zones of the resin that are intended to form sidewalls of the future mold, and this would then form a mold comprising roughnesses on its resin sidewalls, something which is not desirable because it could lead to the presence of small cavities (or small protuberances depending on the type of resin) on the sidewalls of the timepiece components ultimately produced in such a mold.

The phenomenon of stray irradiating radiation may be caused particularly by an inclined surface 31 of a hollow 30. As a variant, such a stray reflection configuration may also arise in the case of incident irradiating radiation 45 that is not perpendicular to the substrate 20. The existence of stray irradiating radiation is relatively predictable since it is dependent on the geometry of the configuration selected. Thus, as a preference, whenever there is a risk of stray irradiated radiation, the method according to the invention is implemented, this notably comprising the step E32 of applying a treatment having an antireflective effect to the substrate, as described previously, thus completely or partly eliminating the appearance of such stray irradiating radiation and thus guaranteeing the precise manufacturing of a mold as defined by the mask 5.

FIG. 20 illustrates by way of example a risk situation in which incident irradiating radiation 45 is inclined by an angle other than 0° and other than 90° relative to the planar upper surface of the substrate 20. Without an antireflective layer, stray radiation 46 would be formed and would pass through the resin in a zone that is not supposed to be affected. In another variant more particularly corresponding to the case of a substrate having a relief, for example a hollow with an inclined surface, the angle α other than 0° and other than 90° between the incident radiation and the substrate may be the result of the geometry of the substrate. In the example of a substrate having a hollow, as illustrated in FIGS. 5a and 5b, the incident radiation is perpendicular to the plane P1. Because the surfaces of the hollow are inclined, the incident radiation may be reflected and form stray radiation 46. In another variant, it is possible to combine the aforementioned two particular geometries, by using an inclined incident irradiating radiation 45 which will reflect off an inclined surface of a substrate.

In summary, whenever the direction of the incident irradiating radiation is not perpendicular to the surface on which the resin that is to be irradiated is deposited, and/or whenever the substrate comprises inclined surfaces that are not perpendicular to the direction of the incident irradiating radiation, this leads to a risk of stray irradiation of the resin situated outside of the zone irradiated directly by the incident irradiating radiation. Such stray irradiation impairs the definition of the mold by laterally irradiating zones of resin that are not supposed to be irradiated. For example, in the case of the substrate 20 having a planar and polished upper surface 21, the irradiating radiation 45 incident upon a positive resin 40 in a direction perpendicular to the plane P1 will be reflected off the inclined surfaces 31 of the hollow 30 produced in the substrate 20, generating stray reflections forming stray irradiating radiation 46 not perpendicular to the plane P1, as illustrated in FIGS. 5a and 5b.

According to an embodiment variant, the relative position of the substrate and of the irradiating radiation (or of the irradiating radiation source) may change over the course of irradiation, in a mode referred to as “dynamic”. For example, the substrate may be mounted with the ability to rotate, so that its entire circumference can be treated with irradiating radiation by rotating it on itself, as illustrated in FIG. 21. A ring that is chamfered around its entire periphery may thus be obtained by rotating a planar substrate while irradiating the resin.

As a variant, the photosensitive resin may be subjected to irradiating radiation where the angle of incidence of the irradiating radiation relative to the upper surface of the substrate can vary over time.

Note that the preceding steps may also be applied in the same way to the embodiment shown in FIG. 22, as illustrated schematically in FIGS. 23 to 26, which will not be described in detail further.

In embodiment variants, the step E3 of forming at least one sidewall of the mold is performed in a medium having a suitable refractive index, so as to obtain sidewalls having an inclination greater than would be achieved in a standard irradiation configuration, namely by using the same incident irradiating radiation in ambient air. For example, when using photosensitive resin, this step may be performed in glycerin, the refractive index of which is close to that of the resin, so as to obtain irradiation angles in excess of 38°.

FIG. 21 illustrates the principle described above and thus illustrates the corresponding embodiment of the invention, which can be applied to all the embodiments described above. In this embodiment of the invention, the entirety of the mold being manufactured is immersed in the medium 80 of refractive index different from that of air. In order to do that, irradiating radiation 45 is reflected by a mirror 110 so as to reach, at a perpendicular angle, the wall of a vessel, for example made of glass, containing the medium 80 of refractive index different from that of air, for example glycerin. In this example, it has been elected for the photosensitive resin 40 to be irradiated such as to define an angle α by which the resin sidewall is inclined relative to the upper plane of the substrate 20. Thus, in this example, the substrate 20 is covered with a layer of photosensitive resin 40, for example of the SU8 type, over which a mask, for example a transparent soda lime mask rendered locally opaque by the deposition of chrome, to form a mask 5, has been placed. The substrate 20 is inclined by an angle Θ relative to the wall of the vessel and therefore relative to the incident ray 45. In this embodiment, the substrate 20 is mounted with the ability to rotate on itself. At the interface between the medium 80 having a refractive index different from that of air and the material of the layer 90 that forms the mask 5, the radiation is refracted at an angle β measured relative to the normal to said interface. With this proposed configuration it is possible to irradiate the photosensitive resin in a zone 100 at an angle greater than the angle that could be achieved in air (where the maximum limit is 38°), by choosing suitable optical properties for the various materials.

By way of example, let us consider a refractive-index medium 80 formed of glycerin, of refractive index n__{Glycerin}=1.67. Let us consider a photosensitive resin of SU8 type, which likewise has a refractive index n__{SU8}=1.67. The refractive index of air is n=1. The material of the layer 90 is chosen to be transparent soda lime, of refractive index n__{Soda lime}=1.53.

In this example, the desire is to irradiate the SU8 resin locally, defining an angle α =50° for the inclined sidewalls thereof.

According to Snell's law of refraction:

n_{Glycerin}·sin Θ=n_{Soda lime}·sin β=n_{SU8}·sin α

Since n_{Glycerin}=n_{SU8}, then Θ=α

Thus, if the substrate 20 is inclined by an angle Θ=50°, this angle Θ is also the angle of incidence of the radiation 45 on the surface of the mask. At the interface between the glycerin and the soda lime, the radiation is refracted at an angle β=56.7°. The proposed configuration thus makes it possible to irradiate the SU8 resin at an angle of 50°, whereas in air, the maximum limit is 38°.

According to an embodiment variant, the resin sidewalls that form part of the mold may be produced in the way described in document EP3670441, combining at least a step based on traditional photolithography as described hereinabove and at least a step based on two-photon polymerization technology, and therefore on the same technology as that used to form a hollow in the resin of the substrate 20 in the third embodiment of the invention. Such an approach advantageously makes it possible to obtain three-dimensional polymerization according to a predefined pattern.

Furthermore, the resin mold part may be multilayered, by involving at least one step based on traditional photolithography with a first layer made of resin, having a first opening, and a second layer of resin derived for example from a rigid film, having a second opening.

At the outcome of the step consisting in developing the resin, a mold is thus formed from the combination of the substrate and of said resin 40, as explained hereinabove. The substrate 20, potentially a hollow 30 exhibiting at least one inclined surface 31, and the resin sidewall or sidewalls, as defined hereinabove, make it possible to define a complex shape for a timepiece component that is to be manufactured. The resin 40, notably the perfectly-defined sidewalls 40 that it forms leading from the substrate 20, defines the sidewalls of a timepiece component that is to be manufactured.

Note that there are a number of conceivable configurations for the positioning of a sidewall 41 made of resin 40 on the substrate 20 when the latter comprises at least one hollow 30.

According to a first configuration shown in FIGS. 6a and 6b, one resin sidewall 41 may be formed in line with the interface 4 between a hollow 30 and the upper surface 21 of the substrate. In such an instance, a sidewall extends at a perpendicular angle to the plane in which the upper surface of the substrate extends at the salient edge formed at the end of the hollow 30, namely at the periphery of the hollow 30.

The quality of manufacture of the mold has a direct impact on the quality of the timepiece component manufactured in this mold. Now, it would seem that precisely positioning a resin sidewall 41 in line with the salient edge defining the periphery of the hollow 30 as described is not an easy matter. Any misalignment at this junction of a resin sidewall 41 may generate a defect in the mold and then a defect, for example in the form of a protrusion or the like, on the timepiece component manufactured.

In order to reduce this risk, a second configuration, shown in FIGS. 7a and 7b, 26 and 27, consists in producing at least one sidewall 41 inside a hollow 30 in order to dispense with the need for precise positioning at the interface 4. Using such an approach, a hollow 30 is formed which is larger in shape than the timepiece component that is to be manufactured, before being delimited by a sidewall 41 positioned within the hollow.

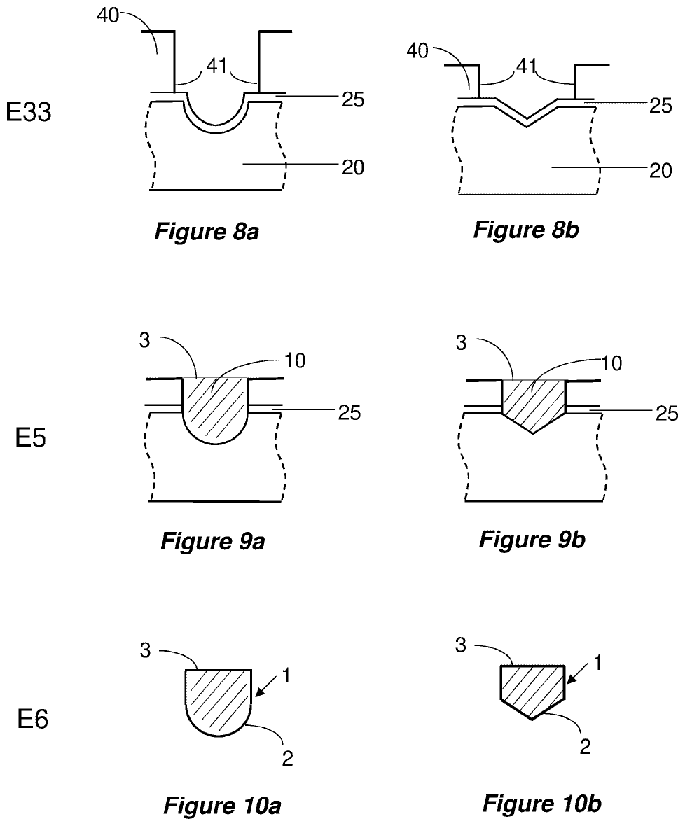

According to a third configuration shown in FIGS. 8a and 8b, the photosensitive resin forms at least one sidewall 41 on the outside of said hollow, which is to say that the resin sidewall extends from the upper surface 21 of the substrate, outside of the interface 4 with a hollow 30.

The invention is not restricted to the embodiments described. By way of example, FIG. 30 illustrates the manufacture of a mold according to a fourth embodiment which combines one of the first two embodiments with the third embodiment. Specifically, the mold comprises first of all at least one hollow 30, formed in a first substrate 20, by applying a method similar to that described with reference to the first two embodiments, and at least one hollow 30′, formed in a second substrate 20′ positioned on the first substrate 20, by applying the third embodiment of the invention. In this fourth embodiment, the first substrate 20 therefore also acts as a support for the second substrate 20′.

Naturally, other embodiments may be envisioned, particularly using an approach similar to FIG. 30, in which the hollows may be formed using different techniques.

Finally, the method for manufacturing a mold may comprise an optional step, not shown, of partial or complete removal E4 of the antireflective layer 25, for example after the sub-step consisting in developing the photosensitive resin that is sensitive to irradiating radiation. Note that such removal of an antireflective layer 25 is not compulsory in all circumstances. Such removal, when implemented, is applied to the substrate 20 belonging to the mold for the manufacture of a timepiece component, namely between the resin sidewalls 41. This removal may be performed mechanically or chemically, for example by stripping or by plasma treatment.

Lastly, as described previously, the method makes it possible to form a mold the bottom of which is formed by part of the upper surface 21 of the substrate, optionally including at least one hollow 30, and possibly comprising an antireflective layer and/or a conductive layer, and the sides of which are defined by resin sidewalls 41. The substrate 20 and the at least one hollow 30 therefore form parts of the mold and under no circumstances do they form part of the future timepiece component that is to be manufactured.

According to one embodiment, the at least one hollow is obtained by a subtractive technique, notably by machining. According to another embodiment, the at least one hollow, or even the sidewalls of the mold is/are obtained, completely or partly, by a two-photon polymerization or stereolithography or grayscale photolithography technique.

The invention also relates to a method for manufacturing a timepiece component per se, of which method the first phase Ph1 consists in implementing the method for manufacturing a mold as described hereinabove. The second phase Ph2 of the manufacturing method relies on using such a mold to manufacture a timepiece component per se. One embodiment of this second phase will now be described.

The second phase Ph2 of the manufacturing method comprises first of all a step consisting in filling E5 all or part of said mold resulting from the first phase with a material of said timepiece component, which will be referred to as the material of the component 10, as illustrated in FIGS. 9a and 9b. This step consisting in filling E5 the mold may comprise an electrodeposition, electroforming, electroplating, slip-casting, or thermoforming step, or a step of filling with the material of the component by casting.

Thus, according to one advantageous embodiment, this filling step may be performed by electroforming of a metallic material. In such a case, it is necessary for the mold to be made at least partly from a conducting material, so that it can act as an electrode for initiation, in view of the future growth of the metallic material of the timepiece component in the mold. Thus, if the substrate is not made from a conducting material, such a conductive layer is added to the substrate in the first phase of manufacturing the mold, as described hereinabove.

In a variant, the mold may be used for casting slip so as to obtain a timepiece component made of ceramic. According to another variant, it is possible to pour or shape a composite material or metallic glass into or in the mold.

The method next comprises a step consisting in detaching E6 (or in other words demolding), from the mold, the timepiece component 1 obtained in the preceding step, as shown in FIGS. 10a and 10b. For this demolding step, the substrate 20 and the at least one hollow 30 therefore exhibit characteristics rendering them suitable for the demolding of the timepiece component 1. In addition, the resin that forms part of the mold is dissolved. This dissolution may be achieved using any means known to those skilled in the art, such as chemical dissolution, the use of deep reactive ion etching DRIE, or laser ablation. In addition to this, and optionally, the component may be detached from the substrate.

It is evident from the method described hereinabove that the entire surface 2 of the timepiece component 1, which surface is formed in direct contact with the mold according to the invention, exhibits a perfect final shape as soon it has been demolded, without requiring an additional operation. The invention thus allows a timepiece component 1 of a complex shape, notably corresponding to a hollow 30 on a substrate and/or to one or more inclined surfaces of a sidewall of the mold, to be manufactured very simply. The timepiece component 1 thus comprises at least one inclined surface, which is at least locally not perpendicular and not parallel to other surfaces of the timepiece component, notably to two main faces that are mutually parallel or inclined relative to that surface of the component that is formed by the bottom of the specific mold.

Optionally, a finishing step may be performed on the opposite face 3 to the bottom of the mold, which face is not formed directly by the mold obtained by the method according to the invention. This finishing step may consist in polishing or grinding this opposite face 3 of the timepiece component, for example to ensure that it is flat. In addition or as a variant, this finishing step may consist in altering the color or tribology properties of at least part of the surface of the timepiece component by the depositing of a coating using a process of physical vapor deposition (PVD), chemical vapor deposition (CVD), atomic layer deposition (ALD) or pulsed laser ablation deposition (PLD). Note that this finishing step is applied to the opposite face 3 of the timepiece component that is not directly in contact with the mold. It can therefore be performed before or after the step consisting in detaching E6 the timepiece component from the mold. As a variant, the finishing step, particularly a coloration step, may be applied to the entirety of the timepiece component.

According to one embodiment, the material of the timepiece component is a metal or metal alloy, notably based on nickel or on gold or on copper. According to another embodiment, the material of the component may be based on ceramic, or based on composite material, namely may be fully or partially comprised of ceramic or of composite material, advantageously containing at least 50 wt % of ceramic or of composite material. The timepiece component is thus predominantly made of metal or of metal alloy, for example based on nickel or on gold or on copper, or is predominantly made of ceramic or of composite material.

The method for manufacturing a timepiece component as described hereinabove is suited to the manufacture of a multitude of different timepiece components. By way of examples, the timepiece component may be a exterior timepiece component such as an applique or a hand, or a component of the movement, such as an escapement wheel, or an escapement lever or else a spring.

The invention also relates to a timepiece component per se. Specifically, it is evident that a major advantage of the invention is that it allows the manufacture of timepiece components of complex shapes, which could not be produced beforehand.

In particular, the invention allows the manufacture of a timepiece component that is characterized in that it is predominantly in monobloc form, preferably produced as a single piece. It may comprise a surface formed by the mold of the invention which comprises a first surface which extends in a first plane, and a second surface which is inclined relative to this first surface, and notably is domed and/or concave and/or convex and/or faceted and/or comprises at least one salient edge, which corresponds to one or more inclined surfaces of one or more hollows of the mold as defined hereinabove. This inclined surface may comprise at least one salient edge, for example in the creation of patterns of the “clous de paris” type, possibly with polished or structured surfaces. The inclined surface may take the form of a surface comprising several inclined portions, notably comprising a profile presenting the form of wavelets. The inclined surface may also comprise salient edges and/or chamfers and/or bevels, sometimes referred to as “anglage” or “angling”. Such an inclined surface may exhibit a predefined roughness.

According to an embodiment variant, the timepiece component may comprise one or more esthetic or functional inserts. For that purpose, the manufacturing method may comprise an intermediate step involving placing at least one insert in the manufacturing mold prior to the step of filling the mold with the material of the component, and involving securing this material of the component to the at least one insert. Such an insert may be a decorative precious stone or a jewel in the horological sense.

Furthermore, advantageously, the timepiece component is manufactured as a monobloc entity, or even as a single piece, with the exception of any insert it might have. As an alternative, the timepiece component or the timepiece may be made up of at least two associated distinct parts, at least one of which originates from the manufacturing method according to the invention.

The invention also relates to a timepiece which comprises at least one timepiece component according to the invention.

The invention also relates to a mold for the manufacture of a timepiece component, characterized in that it comprises a substrate of which at least part of the upper surface forms a bottom of the mold, the mold additionally being at least partially delimited by a resin deposited on said substrate, notably a photosensitive resin, which forms at least part of the sidewalls of the mold.

The resin may form at least one sidewall of the mold in line with the periphery of a hollow in the substrate, and/or the resin may form at least one sidewall of the mold inside a hollow, and/or outside of a hollow, extending from the upper surface of the substrate. In all instances, the resin constitutes all or part of the sidewalls of the mold. The upper surface of the substrate, which forms part of the bottom of the mold, may be planar or non-planar, for example domed, and may or may not comprise at least one hollow.

Said at least one inclined surface of a hollow in the substrate may have an inclination that forms an angle of between 10 and 80 degrees relative to the upper surface of the substrate apart from in said hollow, considered at the interface between this surface and the hollow. This inclined surface may be rounded or formed of a multitude of planar facets, may comprise one or more salient edges and may notably be of concave or convex shape.

The invention thus achieves the desired objects and more generally offers the following advantages:
The manufacturing method is simple to implement and inexpensive
The manufacturing method makes it possible to obtain a timepiece component of complex shape.

The invention will now be illustrated in the context of the actual manufacture of a number of specific timepiece components, selected by way of nonlimiting example.

According to a first example, the timepiece component is a timepiece dial.

The manufacturing method implements the steps according to the embodiments described hereinabove. It will be described succinctly below.

In a preliminary step, the method consists in procuring a ceramic substrate of which the upper surface is non-planar but comprises decorative features, for example in a “clou de paris” pattern with polished facets. The invention allows the addition of decorative features and indexes in order to form the dial from this substrate. The substrate is rendered conductive by using PVD to deposit a thin metal coating on its upper surface.

Next, an antireflective treatment is applied to the substrate by using PVD to deposit a thin antireflective coating consisting of a stack of inorganic layers that cut out more than 99.9% of the reflection of irradiating UV radiation that will be applied. Next, sidewalls made of resin are manufactured, in three sub-steps. First of all, a photosensitive resin SU-8 is coated onto the entire surface of the substrate. This is irradiated perpendicular to the plane P1 through a mask, then the resin is developed. Note that because of the non-planar geometry of the surface of the substrate, the angle between the incident beam of radiation and the resin is not a right angle everywhere. The antireflective layer prevents stray reflections.

The method next implements a step that consists in removing E4 the antireflective coating using an oxygen plasma so as to reveal the electrically conducting metal coating in the openings of the resin mold. A mold is thus obtained which is at least partially delimited by said photosensitive resin, more specifically by said aforementioned resin sidewalls that form the sides of the mold, and by part of said at least one upper surface of the substrate (coated with a thin metal coating), that forms the bottom of the mold, making it possible more specifically to form a mold bottom comprising decorative features.

A fifth step consists in filling E5 the mold produced hereinabove with gold by electroplating. Note that these depositions make it possible to form the decorative features and indexes of the dial.

Finally, the method implements a step consisting in detaching E6 the component from its mold by dissolving the resin by plasma attack. This attack may also remove the antireflective layer and/or the conductive layer. The method finally implements a step consisting in using polishing to finish the face of the decorative features and indexes which completes the electroplating process.

The timepiece component manufactured is therefore in this instance a dial consisting of a ceramic base (which acted as substrate and locally as mold bottom during the method described) which comprises decorative features and indexes made of gold which were manufactured in the mold. In this particular embodiment, the substrate, part of which forms the bottom of the mold, therefore goes on to form part of the timepiece component.

According to a second example, the timepiece component is a hand 50, shown in FIGS. 11 and 12, which comprises an end having a complex visible surface, comprising several distinct inclined portions 52 in the form of three domed-cap portions projecting from the visible upper surface of the hand, with respect to the adjacent domed upper surface 51. These three substantially spherical cap portions have respective axes of revolution A1, A2, A3 which are substantially perpendicular to the upper surface 51 of the hand 50.

The method for manufacturing this hand 50 implements the steps according to the embodiments described hereinabove. It will be described succinctly below.

FIGS. 13 and 14 more specifically show the first step E1 of the method which comprises a sub-step that consists in forming a hollow 30 in a substrate 20 which consists of a flat stainless steel plate or wafer. The upper surface 21 of the substrate 20 is therefore planar before the hollow is formed. The lower surface 23 is likewise planar, and parallel. The hollow 30 is formed by two-stage electrochemical dissolution. A first dissolution stage provides the initial rough form of the domed face of the hand 50, by forming a temporarily hollow 30t, shown in FIG. 13. Next, three hollows 30a, 30b, 30c in the form of concave cap portions are formed in the bottom of the temporarily hollow 30t obtained beforehand, so as to finalize the geometry of the hollow 30, which is shown in FIG. 14. This hollow 30 corresponds to the complex shape of the end of the hand 50 particularly visible in FIG. 12. Note that this hollow 30 thus defines several inclined surfaces 31. The depth d of the hollow is 50 μm.

The second step E2 of the method consists in depositing an antireflective layer 25 on the substrate 20. The antireflective layer 25 is formed of a layer made of the material known by its trade name AZ®-BARLi® II. It is deposited using a method of spin coating.

The third step E3 of the method is the step of forming the mold sidewalls 41 made of resin 40. This step comprises several sub-steps similar to those described hereinabove. First of all, a resin 40 which is a photosensitive resin SU-8 is coated onto the entire surface of the substrate. Next, the resin is irradiated perpendicular to the upper surface 21 of the substrate 20 through a mask, then the resin is developed. The antireflective coating prevents the stray reflections that would otherwise be caused as a result of the shape of the hollows. Note that in this embodiment, the sidewalls 41 are positioned inside the hollow 30. After the resin has been irradiated and developed, the remaining parts of resin 40 and the visible substrate 20 define the mold.

A fourth step of the method consists in removing E4 the antireflective layer 25 in the openings in the resin, which is to say in the bottom of the mold, so as to reveal the substrate 20 as shown in FIG. 15. In this instance the antireflective layer is removed using an oxygen plasma treatment. A mold is thus obtained which is at least partially delimited by said photosensitive resin, more specifically by said aforementioned resin sidewalls that form the sides of the mold, and by part of said at least one upper surface of the substrate, that forms the bottom of the mold.

The fifth step E5 of the method consists in manufacturing the hand 50 by electroforming by filling the mold obtained hereinabove, as shown in FIG. 16. Because the substrate 20 is manufactured in an electrically conducting material, the electroforming method may begin and continue as a continuation of the growth initiated on the conducting zone, along the sidewalls 41 made of photosensitive resin. The hand 50 may for example be made from nickel or from gold.

The sixth step in the method consists in detaching E6 the complex-shaped hand from its mold. The resin is dissolved and the hand 50 is separated from the substrate. The inclined face of the hand exhibits polished surfaces corresponding to the hollow 30 (and to the hollows 30a, 30b, 30c that it comprises) made in the substrate 20, having dimensions and gradients that strictly conform to the required geometry. This visible surface defined by the mold cavity of the hollow 30 on the substrate is used directly at the end of this step E6, without post treatment, which is to say without rework and without tribofinishing. The geometry of this as-molded surface does not undergo cosmetic correction.

The opposite face 53 of the hand is the result of the end of growth of electroplated material: this opposite face 53 may be polished and brought to the required level before or after demolding.

The hand may thus exhibit for example straight sidewalls or chamfered sidewalls.

The timepiece component may next be colored using any technique known to those skilled in the art (ALD, PVD, PLD, pad printing, etc.).

According to a third example, the timepiece component is an escapement wheel 60, shown in FIG. 17, of which the shape, particularly the beveled teeth, requires the support to be angled and rotated relative to the irradiating beam, according to another variant of the manufacturing method.

The manufacturing method consists in procuring a substrate 20 which consists of a planar and polished stainless steel plate or wafer. The upper surface 21 of the substrate 20 prior to machining is planar and corresponds to the plane P1 defined hereinabove.

The second step E2 of the method consists in depositing an antireflective layer 25a on the substrate 20. The antireflective layer 25a has a thickness of 200 nanometers and is made of a product known by its trade name AZ®-BARLi®. The antireflective layer 25a formed is able to completely attenuate the UV reflection on the substrate. It is also an electrical insulator.

The third step E3 is the step of forming the mold sidewalls 41 made of resin. This step comprises several photolithography sub-steps similar to those described hereinabove. First of all, a resin 40a which is a photosensitive resin SU-8 is coated onto the entire surface of the substrate 20. It is irradiated through a mask, so as to produce the inclined sidewalls of the first level of the wheel, notably at the level of the tips of the teeth, by applying an angle α between the upper surface 21 of the substrate and the irradiating source (the angle is then due to the orientation of the substrate). In order for this same angle to be present on each tooth, the fixture is able to rotate (dynamic mode) relative to the center of the future wheel. Because the angle of the teeth is greater than 38°, the entire assembly comprising the fixture and the substrate covered with SU-8 is immersed in glycerin during irradiation. The resin is then developed.

An antireflective layer 25b is applied by spin coating to the substrate comprising the layer 25a and to the structures made of resin 40a. The resin sidewalls of the second level of the mold are then formed in three sub-steps. A resin 40b which is a photosensitive resin SU-8 is coated onto the entire surface covered by the layer 25b. It is irradiated through a mask, so as to produce the second level of the mold of the wheel, by applying an angle of 90° between the plane P1 of the substrate 20 and the irradiating radiation. The antireflective layer 25b is needed because of the shape of the substrate which, at this stage, consists partially of the sidewalls of the part made of resin 40a which are inclined with respect to the irradiating radiation.

Depending on the angles of irradiation, the resin may be:
Reflective, which would generate stray irradiation, or
Transparent, such that the incident radiation would reach the substrate, generating a reflected radiation which, on reaching the resin/air interface, would once again represent a risk of stray irradiation.

The above observations mean that the antireflective coating is indeed necessary. It may be noted that the sidewalls which are upright over their entire height are produced directly during this step. The resin is developed. A detail of the result obtained at this stage is illustrated in FIG. 18.

A fourth step of the method consists in removing E4 the antireflective layer in the openings in the resin, which is to say in the bottom of the mold, using an oxygen plasma, so as to reveal the metal substrate 20. In this instance the antireflective layer is removed using an oxygen plasma treatment. A mold is thus obtained which is at least partially delimited by said photosensitive resin, more specifically by said aforementioned resin sidewalls that form the sides of the mold, and by part of said at least one upper surface of the substrate, that forms the bottom of the mold.

The fifth step E5 of the method consists in manufacturing the escapement wheel by electroforming by filling the mold obtained hereinabove, as shown in FIG. 19. Advantageously, use is made of an amorphous paramagnetic alloy based on nickel and on phosphorus. Because the growth process is isotropic, the filling of the mold begins at the conducting upper surface of the plate or wafer and continues, growing wider, at the inclined sidewalls, according to the chamfer formed by the mold.

The sixth step of the method consists in detaching E6 the escapement wheel 60 by dissolving the resin and detaching from the substrate.

The rear face of the wheel resulting from the end of the growth of electroplated material is finished by being brought to the required level and polished before or after demolding.

The component obtained is an escapement wheel 60 exhibiting flanks that are partially inclined at its teeth 61. Because of the good resolution of the inclined resin sidewalls of the mold in which the escapement wheel is manufactured, these flanks do not require any mechanical cosmetic correction. The same is true of that face of the wheel that “comes from” the substrate, namely that was in contact with the substrate 20 up to the demolding step.

1. A method for manufacturing a mold for the manufacture of a timepiece component, comprising:
procuring at least one substrate comprising an upper surface;
applying a treatment having an antireflective effect to all or part of the upper surface of the substrate; then
depositing a layer of photosensitive resin on the upper surface of the substrate;
irradiating the photosensitive resin with an irradiating radiation according to a predefined pattern; then
developing the photosensitive resin,
so as to form a mold at least partially delimited by the photosensitive resin and by part of the upper surface of the substrate.

2. The method for manufacturing a mold as claimed in claim 1, wherein
the irradiating of the photosensitive resin uses the irradiating radiation applied to at least one zone of the substrate at an angle of incidence not perpendicular to the upper surface of the substrate to which a treatment having an antireflective effect has been applied, and/or
the irradiating of the photosensitive resin with the irradiating radiation is performed with an angle of incidence of the irradiating radiation relative to the upper surface of the substrate that is variable over time and/or with a position of the irradiating radiation relative to the upper surface of the substrate that is variable over time.

3. The method for manufacturing a mold as claimed in claim 1, wherein the applying of the treatment having the antireflective effect comprises depositing the antireflective layer on the substrate performed by coating or by spin-coating or by spray-coating or by dip-coating, or by chemical vapor deposition (CVD) or by physical vapor deposition (PVD), or by atomic layer deposition (AVD) or by pulsed laser ablation deposition (PLD).

4. The method for manufacturing a mold as claimed in claim 1, wherein the irradiating of the photosensitive resin with the irradiating radiation is performed in a medium having a refractive index different from a refractive index of air, so as to increase an angle of incidence of the radiation in the resin relative to the upper surface of the substrate in comparison with an identical configuration in air.

5. The method for manufacturing a mold as claimed in claim 4, wherein the substrate, the resin and a mask for the irradiation of the resin are positioned inside a vessel containing the medium having the refractive index different from the refractive index of air.

6. The method for manufacturing a mold as claimed in claim 1, comprising carrying out partial or complete removal of an antireflective layer after the developing of the photosensitive resin following the irradiation with the irradiating radiation.

7. The method for manufacturing a mold as claimed in claim 1, wherein the substrate has a shape of a plate or wafer made of a material selected from the group consisting of a metal, silicon, glass, ceramic, polymer, and composite.

8. The method for manufacturing a mold as claimed in claim 1, wherein the procuring of the substrate comprises creating a hollow starting from the upper surface of the substrate, the hollow being delimited by at least one inclined surface that is inclined relative to a plane in which the upper surface of the substrate extends apart from in the hollow, prior to implementation of the applying of the treatment having the antireflective effect to all or part of the upper surface of the substrate, so that the treatment having the antireflective effect is performed on at least part of the inclined surface of the hollow.

9. The method for manufacturing a mold as claimed in claim 8, wherein the creating of the hollow forms the at least one inclined surface having an inclination that forms an angle in a range of from 10 to 80 degrees relative to the upper surface of the substrate apart from in the hollow and measured at the interface between the upper surface and the hollow.

10. The method for manufacturing a mold as claimed in claim 8, wherein the creating of the hollow uses a two-photon polymerization or stereolithography or grayscale photolithography technique.

11. A method for manufacturing a timepiece component, comprising:
manufacturing a mold by the method as claimed in claim 1, and
forming the timepiece component, comprising filling all or part of the mold with a material of the component.

12. The method for manufacturing a timepiece component as claimed in claim 11, wherein the filling of the mold comprises carrying out an electrodeposition, electroforming, electroplating, slip-casting, or thermoforming, or filling with the material of the component by casting.

13. The method for manufacturing a timepiece component as claimed in claim 11, comprising detaching, from all or part of the mold, the timepiece component obtained via the filling of the mold.

14. The method for manufacturing a timepiece component as claimed in claim 11, comprising carrying out a finishing comprising polishing or grinding a face of the timepiece component that is not in contact with the mold, in order to ensure the flatness thereof.

15. The method for manufacturing a timepiece component as claimed in claim 11, wherein the material of the component is selected from the group consisting of a metal, a metal alloy, a ceramic, and a composite material.

16. The method for manufacturing a timepiece component as claimed in claim 11, wherein the timepiece component is a timepiece ornamentation component or a component of a movement.

17. The method for manufacturing a mold as claimed in claim 2, wherein the irradiating of the photosensitive resin uses the irradiating radiation applied to at least one zone of the substrate at an angle of incidence that forms an angle in a range of from 10 to 80 degrees relative to the upper surface of the substrate in the zone.

18. The method for manufacturing a mold as claimed in claim 9, wherein the creating of the hollow forms the at least one inclined surface having a rounded shape or made up of a multitude of facets or comprising at least one salient edge and/or being of a concave shape or a convex shape.

19. The method for manufacturing a timepiece component as claimed in claim 14, comprising altering a color or tribology properties of at least part of the surface of the timepiece component by depositing a coating using a process of physical vapor deposition (PVD), chemical vapor deposition (CVD), atomic layer deposition (ALD) or pulsed laser ablation deposition (PLD).

20. The method for manufacturing a timepiece component as claimed in claim 15, wherein the material of the component is selected from the group consisting of a nickel-based metal alloy, a gold-based metal alloy, and a copper-based metal alloy.
